(19) United States
(12) Patent Application Publication
(10) Pub. No.: US 2009/0114618 A1
(43) Pub. Date: May 7, 2009

(54) METHOD OF MAKING HIERARCHICAL ARTICLES

(75) Inventors: Jun-Ying Zhang, Woodbury, MN (US); Terry L. Smith, Roseville, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/124,302

(22) Filed: May 21, 2008

Related U.S. Application Data
(60) Provisional application No. 60/999,753, filed on Jun. 21, 2007.

(51) Int. Cl. B44C 1/22; G03F 7/20

(52) U.S. Cl. 216/42; 430/323

(57) ABSTRACT

Provided is a method of making hierarchical structures that contain nanofeatures and microstructures. The method includes adding the nanofeatures to existing microstructures using nanoparticles as an etch mask.

### RELATED APPLICATION

This application claims priority to U.S. patent application Ser. No. 11/766,412, now U.S. Provisional Application No. 60/999,753, filed Jun. 21, 2007, which is herein incorporated by reference in its entirety.

### FIELD

This application relates to methods for making hierarchical structures and in particular structures that contain nanofeatures and microstructures.

### BACKGROUND

There is an interest in commercial and industrial applications to reduce the size of articles and devices. This is particularly true in the area of electronics where devices have been made smaller and smaller. Nanostructured devices, for example, can be used in articles such as flat panel displays, chemical sensors, and bioabsorption substrates. Microstructured surfaces have found commercial utility in, for example, electroluminescent devices, field emission cathodes for display devices, microfluidic films, and patterned electronic components and circuits. There are many applications for which it would be desirable to make hierarchical structures where smaller structures (nanofeatures, for example) are present upon larger structures (microstructures, for example). These applications include sensors, optical devices, fluidic devices, medical devices, molecular diagnostics, plastic electronics, micro-electromechanical systems (MEMS) and nano-electromechanical systems (NEMS). Also, recently there has been an interest in trying to understand and mimic adhesive mechanisms in nature such as those on the gecko's feet. Studies have revealed that the gecko has micro/nanoscale features on its feet that can stick firmly to any kind of surface, but can also release effectively with minimal effort.

It is known to add nanofeatures to existing microstructure. This has been accomplished, for example, by growing nanocrystals onto microstructured surfaces, nanoimprinting microstructured surfaces, and using interferometric lithographic techniques to make submicron or nanoscale gratings and grids on microsubstrates for optical applications. However these techniques are very costly and are not always very suitable for large area patterns or mass production.

### SUMMARY

There is a need for low cost, high-throughput, methods of making hierarchical structures comprising both nanofeatures and microstructures that are suitable for large area patterns and mass production. The method presented herein fabricates hierarchical articles, that include nanofeatures on microstructures, using nanoparticles as an etch mask for high energy ablative processes.

In one aspect, provided is a method of making an article comprising providing a substrate comprising microstructures, adding nanoparticles to the microstructures, and etching away at least a portion of the microstructures to form nanofeatures using the nanoparticles as an etch mask, wherein the nanoparticles etch at a substantially slower rate than the substrate.

In another aspect, this invention provided is a method of making a replica comprising providing a substrate comprising microstructures, adding nanoparticles to the microstructures, etching away at least a portion of the microstructures, using the nanoparticles as an etch mask, to form a hierarchical article, adding a polymer to the hierarchical article, and separating the polymer from the hierarchical article to produce a replica, wherein the nanoparticles etch at a substantially slower rate than the substrate.

In this application:

the articles “a”, “an”, and “the” are used interchangeably with “at least one” to mean one or more of the elements being described;

the term “etching agent” refers to an agent used to remove material from a substrate and can be a wet etching agent as, for example, an acid bath, or a dry etching agent such as, for example, reactive ions from a plasma, or a high energy laser beam;

the term “etch mask” refers to a structure that is held in proximity to or in contact with the substrate so as to allow or to prevent exposure of regions of the substrate to optical or etchant beams;

the term “etch resist” refers to a layer or layers of material that is placed on the substrate and can be patterned to form a resist pattern, which, under the etching conditions used, etches more slowly than the substrate;

the term “hierarchical” refers to constructions that have two or more elements of structure wherein at least one element has nanofeatures and at least another element has microstructures. The elements of structure can consist of one, two, three, or more levels of depth;

the terms “microstructure” or “microstructures” refer to structures that range from about 0.1 microns to about 1000 microns in their longest dimension. In this application, the ranges of nanofeatures and microstructures overlap;

The terms “nanofeature” or “nanofeatures” refer to features that range from about 1 nm to about 1000 nm in their longest dimension. The nanofeatures of any article of this application are smaller than the microstructure generated on the article;

the term “negative relief image” refers a three-dimensional replication of an article that contains an inverted topological structure of the original article;

the terms “pattern” or “patterns” refer to a configuration or configurations that can include regular arrays or random arrays of features or structures or a combination of both; and

the term “resist” refers to a layer or layers of material that is placed on the substrate to selectively allow an etching agent to pass through in a patterned manner.

The above summary of the present invention is not intended to describe each disclosed embodiment of every implementation of the present invention. The Figures and the detailed description which follow more particularly exemplify illustrative embodiments.

### BRIEF DESCRIPTION OF THE DRAWINGS

FIGS. 1a-1e illustrate an embodiment of this invention for making hierarchical structures comprising microstructures that are normal to the substrate plane

FIGS. 2a-2e illustrate an embodiment of this invention for making hierarchical structures comprising microstructures that are at an angle other than normal to the substrate plane.

FIGS. 3a and 3b are photomicrographs of Example 1.

FIG. 4 is a photomicrograph of Example 2.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Provided is a method of making an article comprising providing a substrate comprising microstructures, adding nanoparticles to the microstructures, and etching away at least a portion of the microstructures to form nanofeatures using the nanoparticles as an etch mask, wherein the nanoparticles etch at a substantially slower rate than the substrate.

The hierarchical surface can be used directly for its intended purpose or a mold can be made from the hierarchical surface by adding a polymer to the surface, solidifying the polymer and separating the solidified polymer from the surface to form a mold that has a negative relief image of the original hierarchical surface. This mold can be used to produce replicas of the original surface. With application of appropriate protective coatings and/or release coatings, many molds can be made from the original hierarchical surface, many replicas can be made from the original mold or molds or many more molds can be made from the second generation replicas. The replicas can be used for their intended purpose or can be used to make multiple additional molds for mass production.

The substrate can be selected from a variety of materials. These materials include polymeric films such as, for example, polyimide or polymethylmethacrylate, or inorganic materials such as metals, glasses, silicon wafers, and silicon wafers with coatings. The coatings on the silicon wafers can include polymer film coatings such as, for example, polyimides or urethane acrylates, or can include inorganic coatings such as, for example, an SiO₂ coating.

The substrate comprises microstructures. The microstructures can be formed directly in the surface of the substrate by ablative processes. Alternatively, the microstructures can be formed in a layer or layers added to the substrate. Additionally, the microstructures and the substrate can be formed in one process at the same time.

Microstructures can be formed directly in the substrate by, for example, subtractive processes. Microstructures can be formed subtractively in a substrate by removing existing material using a high energy beam process such as laser ablation, ion beam etching, deep UV lithography, interference lithography, inclined lithography, electron beam lithography or reactive ion etching, to name a few. This can be particularly useful when the substrate is an inorganic material such as a metal, or ceramic as, for instance, silicon or silicon dioxide. Microstructures can also be formed ablatively in some polymer substrates such as, for example, polyimide. A high energy beam can be scanned under the direction of a computer program to remove desired patterns of material under a rastered or digitally-pulsed beam. Alternatively, the high energy beam can be passed through an etch mask. The etch mask can be a photomask (such as a glass or plastic plate with patterns of high density material deposited on it which resist passage of the beam and patterns without high density material which are transparent to the beam). Alternatively, the etch mask can be an aperture mask. Aperture masks are made of metal or other high density materials such as metal oxides that have patterned openings through which the high energy beams can pass. When the etch mask is placed close to or in direct contact with the substrate it is referred to as a contact mask.

The microstructures can be formed at right angles (90° or normal) to the plane of the substrate surface or the contact mask, if one is used. Alternatively, the microstructure can be formed at an oblique angle to the plane of the substrate or the plane of the contact mask, if one is used. If the microstructure is formed at an oblique angle (one other than about 90° to the plane of the substrate or the plane of the contact mask) the resulting structures can be referred to as “angled posts”. Angled posts can be formed ablatively by directing a high energy beam towards the substrate at an oblique angle to the surface of the substrate. Angled posts can be made using methods such as inclined lithography. Inclined lithography is described for example, in Beuret et al., IEEE Micro Electro Mechanical Systems, Oiso, Japan, January 1994, pp. 81-85, and Han et al., Sensors and Actuators A, 111, 14-20 (2004). Angled posts can be made at angles of less than about 85.5°, less than about 78°, less than about 70°, less than about 65°, less than about 60° or even less than about 45° to the plane of the substrate.

The microstructures can also be formed by adding a material to the substrate. The material can include the microstructure when it is added to the substrate, or the material can be added to the substrate and then subsequently have the microstructure generated in it. The microstructure can be formed in the material before it is added to the substrate. The microstructure can be added to the material subtractively using the methods herein. The microstructure can also be cast into the added material. For example, a replica with a negative relief article of the microstructure can be used to form the microstructure in the material. In this case, the material can be a thermoplastic material that flows at a high temperature and then becomes solid at room temperature or at use temperature. Alternatively, the material can be a thermoset and can be cured using a catalyst, heat, or photoexposure depending upon its chemistry. When the material is added to the substrate it can be added as a solid. The material can be added to the substrate by lamination or by adding a thin adhesive material. Materials that can be used for this purpose include thermoplastic polymers that flow at elevated temperatures but not at lower temperatures such as room temperature. Examples of thermoplastic polymers that can be used include acrylics; polyolefins; ethylene copolymers such as polyethylene acrylic acid; fluoropolymers such as polytetrafluoroethylene and polyvinylidene fluoride; polyvinylchloride; ionomers; ketones such as polyetheretherketone; polyamides; polycarbonates; polyesters; styrene block copolymers such as styrene-isoprene-styrene; styrene butadiene-styrene; styrene acrylonitrile; and others known to those skilled in the art. Other useful materials for forming a substrate with nanofeatures include thermosetting resins such as, for example, polydimethylsiloxanes, urethane acrylates and epoxies. An example of thermosetting resins can be a photocrosslinkable system, such as a photocurable urethane acrylate, that forms a polymeric substrate with microstructures upon curing.

When addition of a material to the substrate is used to produce the microstructures, a number of materials can be used. For example, a photoresist (negative or positive) can be added to the substrate. The photoresist can be exposed to light passing through a photomask or projected through a lens system to produce microstructures. Additionally, interference lithography can be used to produce the microstructures. Interference lithography is discussed, for example, in S. R. J. Brueck, “Optical and Interferometric Lithography-Nanotechnology Enablers”, Proceedings of the IEEE, Vol. 93 (10), October 2005. The exposed (positive photoresist) or unexposed (negative photoresist) areas can then be removed by using a developing solution to dissolve the undesired photoresist. The resist can then be hardened by physical or chemical means for use in later steps. It is also contemplated that the photoresist can be exposed by directly writing with a rastered or digitally-pulsed laser beam, or by interference lithography as is known in the art. The developed photoresist can then be hardened and used as described herein. Useful photoresists include negative photoresists such as UVN 30 (available from Rohm and Haas Electronic Materials, Marlborough, Mass.), and FUTURREX negative photoresists (available from Futurrex, Franklin, N.J.), and positive photoresists such as UV5 (available from Rohm and Haas Electronic Materials) and Shipley 1813 photoresist (Rohm and Haas Electronic Materials). Other photopolymers can be used to generate the microstructures. Any photopolymer system known to those skilled in the art can be used that can be used to form microstructures upon exposure to radiation (UV, IR, or visible).

As another alternative, the microstructures and the substrate can be formed at the same time. For example, a curable polymer system can be used to make microstructure as a part of a substrate using a mold. If the system is allowed to cure while in contact with a microstructured surface it will produce a negative relief image of the surface. The bulk of the cured polymer system can be used as the substrate. If a photopolymer system is used, it can be cured by a patterned radiation source or it can be cast in a transparent mold and photocured. In this manner, a substrate can have microstructure without the need to add a layer.

It is also contemplated that the microstructure and the substrate can be formed by a photopolymer with a two-photon initiation system such as those disclosed in, for example, U.S. Pat. No. 6,750,266 (Bentsen et al.). With a two-photon system polymerization, the microstructures can be formed by polymerizing the microstructured features using a two-photon fabrication system such as that disclosed in, for example, U.S. Ser. No. 11/531,836 (Faklis et al.). In such a system direct photo-crosslinking of three-dimensional objects is possible and the microstructure can be directly written into the photopolymer. As with conventional photochemical generation, the unpolymerized portion of the two-photon system is removed by use of an appropriate solvent to reveal at least a portion of the original substrate.

The method of making hierarchical structures includes adding nanoparticles to the microstructures wherein the nanoparticles etch at a substantially slower rate than silicon dioxide, and wherein the etch mask comprises nanoparticles. Useful nanoparticles for this invention include nanoparticles that can be applied as a dispersion and remain dispersed on the microstructures. Nanoparticles can be made dispersible in solvent systems by either modifying the surface of the nanoparticles or by adding a dispersant to the solvent system or both. Typical surface modifications include adding a surface modifying agent to the nanoparticles and allowing the surface modifying agent to react with the nanoparticles. Useful surface modification processes are described, for example, in U.S. Pat. Nos. 2,801,185 (Iler) and 4,522,958 (Das et al.) and PCT Pat. Appl. No. WO 2006/083431 (Baran et al.) all of which are incorporated herein by reference.

Alternatively, dispersants can be added to the solution to make the nanoparticles remain dispersed in the solvent system. For example, dispersants such as polyurethanes, polyacrylates such as, for example, EFKA polyacrylates available from CIBA Specialty Chemicals, Tarrytown, N.Y., dodecylbenzenesulfonic acid available from Aldrich Chemical, Milwaukee, Wis. can be used to disperse nanoparticles. Some nanoparticle dispersions are available commercially such as, for example, indium-tin oxide dispersions under the tradename, ITO-SOL, available from Advanced Nano Products Co., Ltd., Chungcheonbuk-do Korea, or SiO₂ particle dispersions such as are available from Nalco Specialty Chemicals, Naperville, Ill. The nanoparticles can function as an etch mask for further processing of the microstructures. The nanoparticles can be dispersed and can, optionally, be combined with a binder to make them immobile on the surface of the added layer.

The nanoparticles of this invention comprise nanoparticles that etch at a substantially slower rate than the substrate. Table I provides the etch rate for a number of substrate and nanoparticle materials. Polymers, such as polyimide and photoresists, are known to etch at a much faster rate than any of the inorganics listed in Table 1.

TABLE I
Reactive Ion Etching Rates for Metal Oxides
(C₄F₈ and O₂ process gasses)

| Materials | Etch rate | |
|---|---|---|
| Indium-tin oxide (ITO) | 30-70 | nm/min |
| Si | 100-200 | nm/min |
| A12O3 | 65-80 | nm/min |
| TiO2 | 100-l50 | nm/min |
| SiO2 | 400-600 | nm/min |

Nanoparticles that can be useful as an etch mask include oxides such indium-tin oxide, silicon dioxide, titanium dioxide, zirconium dioxide, tantalum oxide, hafnium oxide, niobium oxide, magnesium oxide, zinc oxide, indium oxide, tin oxides, and other metal or metalloid oxides. Other useful nanoparticles include nitrides such as silicon nitride, aluminum nitride, gallium nitride, titanium nitride, carbon nitride, boron nitride and other nitrides known by those skilled in the art to be nanoparticles. It is also possible to use metal nanoparticles as an etch mask. Metal nanoparticles can include, for example, aluminum, copper, nickel, titanium, gold, silver, chromium, and other metals. Indium-tin oxide (ITO) nanoparticles have been found to be disperable in isopropanol and adherent to polyimide films and can be used as an etch mask without modification or the addition of other additives. Other nanoparticles can be dispersible with the addition of surface modification groups as known by those skilled in the art.

Nanofeatures can be formed on the microstructures by ablative processes using the dispersed nanoparticles as an etch mask. The ablative processes that are useful in this step include any of the high energy ablation processes useful to form the microstructures. The nanofeatures can be formed ablatively by removing existing material using a high energy beam such as laser ablation, ion beam etching, deep UV lithography, nanoimpring lithography, electron beam lithography or reactive ion etching to name a few. For example, reactive ion etching can be used to remove parts of the substrate or materials added to the substrate in a manner so as to generate nanofeatures. In reactive ion etching, a reactive gas species, such as C₄F₈ or SF₆, is added to a reaction chamber. A plasma is generated by applied radio frequency (RF) potentials. This causes the gas molecules to be broken down into a number of fragments and radicals, a significant number of which become ionized. These ionized particles can be accelerated towards various electrode surfaces and can etch or dislodge molecules from the surface they impinge upon. The result is that material on the microstructures is removed where the high energy beam is able to reach the surface (for example, between the nanoparticles). The material on the microstructures that is shielded from the high energy beam by the dispersed nanoparticles is not ablated. The result is that the microstructures have nanofeatures that can be in the form of for example, nanoposts, where the nanoparticles can act like as an etch mask and protect the microstructure from ablation.

In another aspect provided is a method of making a replica comprising providing a substrate comprising microstructures, adding nanoparticles to the microstructures, etching away at least a portion of the microstructures, using the nanoparticles as an etch mask, to form a hierarchical article, adding a polymer to the hierarchical article, and separating the polymer from the hierarchical article to produce a replica, wherein the nanoparticles etch at a substantially slower rate than the substrate.

Polymers useful for forming the replica can include thermoplastic polymers and thermosetting polymers known to those skilled in the art. Thermoplastic polymers can include materials that soften or melt above room temperature but that are rigid and can hold structure when at or below room temperature. Thermosetting polymers can also be useful for forming replicas. Thermosetting polymers that are useful include polysiloxanes and urethane acrylates. For the replication of nanofeatures and microstructures, the polymers used to form the replica can have low viscosity. This can allow the polymer to flow into and around the small features of the article. It can be useful to apply the polymer to the article under vacuum so that air entrapment between the article and the polymer is minimized.

It can be advantageous to apply a release coating to the hierarchical article before forming a replica. If the hierarchical article is made from SiO₂, SiN, or other inorganic or polymeric materials, the article can be coated with a fluorosilane release agent such as, for example, trimethychlorosilane or fluorinated siloxanes such as those disclosed in U.S. Pat. No. 5,851,674 (Pellerite et al.). Also useful for this purpose are hexafluoropolyprolylene oxide derivatives such as those disclosed in U.S. Pat. No. 7,173,778 (Jing et al.). These disclosures are hereby incorporated by reference.

Alternatively, the article can be metallized with, for example, a thin layer of nickel that has been vapor deposited or deposited by electroless plating. If the article is metallized it can also be advantageous to put a release agent on the metallized article to enhance the release of the polymers that form the replica. For example, the article can be coated with a release layer such as a fluorinated phosphonic acid as disclosed in U.S. Pat. No. 6,824,882 (Boardman et al.) or perfluoropolyether amide-linked phosphonates such as those disclosed in U.S. Pat. Publ. No. 2005/0048288 (Flynn et al.). It is also contemplated that the hierarchical article can be protected by coating with diamond-like glass as disclosed, for example in U.S. Pat. No. 6,696,157 (David et al.). These disclosures are hereby incorporated by reference.

The replica-forming polymers can be placed in contact with the hierarchical article (with or without a protective coating), cured by any of a variety of means including heat, moisture or radiation, and then separated from the article to produce a negative relief image (replica) of the article. The replicas can be used to produce secondary or daughter molds of the original article.

The replica-forming polymers can be placed in contact with the hierarchical article (with or without a protective coating), cured by any of a variety of means including heat, moisture or radiation, and then separated from the article to produce a negative relief image (replica) of the article. The replicas can be used to produce secondary or daughter molds of the original article. In this application, although the term replica and mold can be used interchangeably depending upon whether the article or its replica is used as the final product, it is assumed that the original article is a negative mold used to prepare positive replicas.

The articles of this invention can be used for a variety of purposes.

The figure sequences 1a-1e and 2a-2e illustrate some embodiments of a method of making an article comprising providing a substrate comprising microstructures, adding nanoparticles to the microstructures, and etching away at least a portion of the microstructures to form nanofeatures using the nanoparticles as an etch mask, wherein the nanoparticles etch at a substantially slower rate than the substrate.

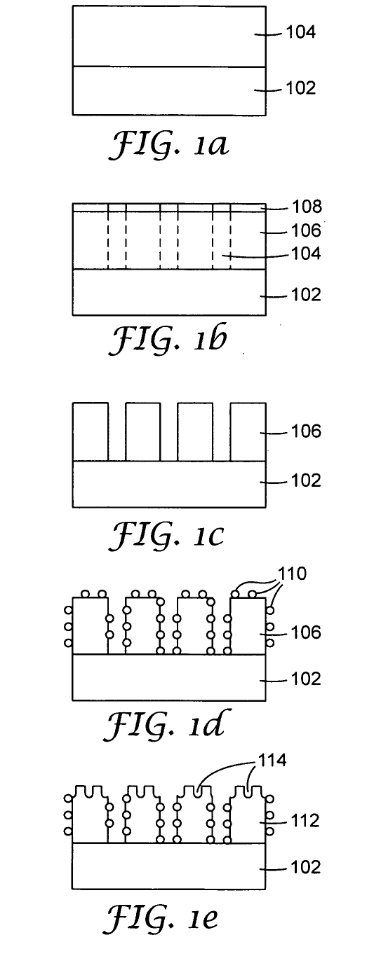

FIG. 1a illustrates an embodiment of making hierarchical structures wherein the microstructure is at 90° or normal to the substrate plane. FIG. 1a provides substrate 102 that can be, for example, a silicon wafer. In this embodiment negative photoresist 104 is coated onto the substrate. In FIG. 1b, contact mask 108 is placed on the photoresist layer and the photoresist is exposed to ultraviolet radiation. This results in areas of unexposed photoresist 104 and areas of exposed photoresist 106. In the exposed areas, the photoresist has been crosslinked and is not insoluble in solvents. The contact mask is removed and a development solution is used to remove the soluble, unexposed regions. The result is shown in FIG. 1c and consists of substrate 102 with microstructures 106. The substrate with microstructures is then coated with a dispersion of nanoparticles. Indium-tin oxide nanoparticles are an example of useful nanoparticles. FIG. 1d shows substrate 102 with microstructures 106 coated with nanoparticles 110. The nanoparticles 110 act as an etch mask for reactive ion etching of the microstructures. The result is shown in FIG. 1e and consists of substrate 102 with microstructures that have nanopits 114 where the nanoparticles did not shield the reactive ion beam from the microstructure.

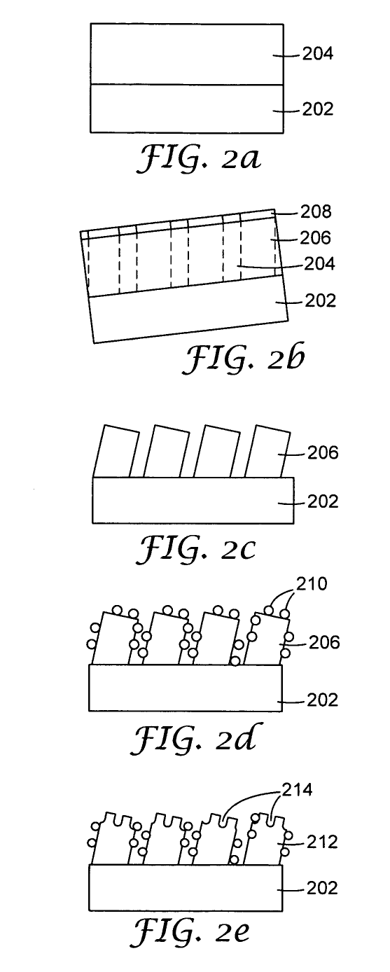

The second figure sequence 2a-2e shows another embodiment of this invention. As shown in FIG. 1a, substrate 202 is coated with negative photoresist 204. Then the substrate is turned at an oblique angle to the plane of the contact mask and exposed to ultraviolet radiation through contact mask 208 as shown in FIG. 2b. This exposure forms uncrosslinked areas of photoresist 204 and crosslinked areas of photoresist 206 that are at an angle other than 90° with respect to the substrate 202. After development, as shown in FIG. 2c, substrate 202 has angled microstructure 206 on it. FIG. 2d shows substrate 202 and angled microstructure 206 that have been coated with nanoparticles 210. After reactive ion etching the result is shown in FIG. 2e in which there is substrate 202 with angled (inclined) microstructure that has nanopits 214.

Objects and advantages of this invention are further illustrated by the following examples, but the particular materials and amounts thereof recited in these examples, as well as other conditions and details, should not be construed to unduly limit this invention. Unless otherwise stated or apparent, all materials used in the following examples are commercially available.

### EXAMPLES

### Example 1

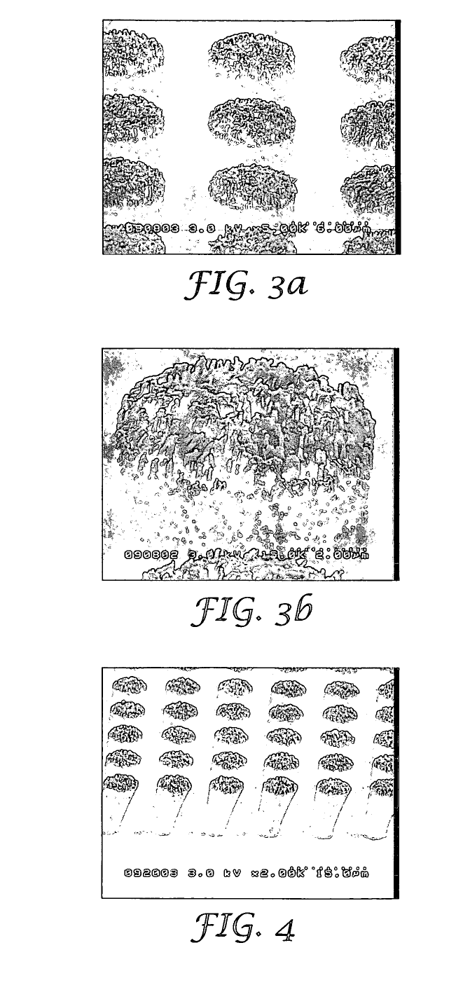

An antireflective coating (ARC UV-112, available from Brewer Science, Rolla, Mo.) was applied to the surface of a silicon wafer (available from Montco Silicon Technologies, Inc., Spring City, Pa.). A 21 μm layer of SU-8 negative photoresist (available from MicroChem Corp., Newton, Mass.) was coated onto the antireflective coated silicon wafer by spin coating at 2000 r.p.m, followed by baking at a temperature of 65° C. for 2 minutes and then 95° C. for 2 minutes. The photoresist was exposed through a contact mask at a tilt of 4.5° from the normal to the plane of the contact mask using an inclined exposure lithography system. Inclined lithography is described for example, in Beuret et al., IEEE Micro Electro Mechanical Systems, Oiso, Japan, January 1994, pp. 81-85, and Han et al., Sensors and Actuators A, 111, 14-20 (2004). After the exposure, a post-exposure bake at 65° C. for 2 minutes followed by 95° C. for two minutes was performed to selectively crosslink the exposed portions of the photoresist. The photoresist was then developed in propylene glycol methyl ether acetate (PGMEA) and dipped into a solution of indium-tin oxide (ITO) nanoparticles (available from Advanced Nano Products Co., Ltd., Chungcheonbuk-do, Korea) 1 wt % suspended in a 1:1 by volume solution of isiopropanol:water to give microstructures (microposts) covered with ITO nanoparticles. After drying the microposts were then etched using reactive ion etching (RIE) using the ITO nanoparticles as an etch mask. The RIE was done using a Model PLASMA LAB System 100, available from Oxford Instruments, Yatton, UK. The RF power was 60 watts, the pressure was 15 mTorr, the ICP power was 1900 watts and the gas flow has 2 sccm C₄H₈ and 20 sccm O₂. The etching time was 50 seconds. The result is shown in FIGS. 3a and 3b and shows nanoposts that are between 100 and 200 nm in diameter on top of microstructures (posts) that are about 7 μm in diameter and about 21 μm in height.

### Example 2

Example 2 was performed in a manner identical to Example 1 with the exception that the inclined exposure lithography was performed at an angle of about 12° to the normal to the plane of the contact mask. The result is shown in FIG. 4 and shows nanoposts that have dimensions of 100-200 nm in diameter and about 500 nm in height on top of microposts that are 6 μm in diameter and 21 μm in height.

### Example 3

A mold was formed from above master (Example 2) using poly (dimethyl siloxane) (PDMS). PDMS (available as SYLGARD 184, from Dow Corning, Midland, Mich.) was poured on the patterned SU-8 photoresist with nano-features, and then cured on a hot plate (80° C. for 1 h). After the curing, the PDMS mold was peeled off the SU-8/PI master, yielding the desired two-level structure negative mold. A UV-curing acrylate resin containing PHOTOMER 6210 and SARTOMER 238 (75:25 by weight) (both available from Sartomer, Co., Warrington, Pa.) were used to replicate the hierarchical structure and cured by UV radiation (Fusion “D” lamp, at 600 W/2.54 cm) at a speed 10.7 m/min. The resulting replica is shown in the photomicrograph in FIG. 4.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

What is claimed is:

1. A method of making an article comprising:
providing a substrate comprising microstructures;
adding nanoparticles to the microstructures; and
etching away at least a portion of the microstructures to form nanofeatures using the nanoparticles as an etch mask,
wherein the nanoparticles etch at a substantially slower rate than the substrate.

2. The method of claim 1 further comprising forming the microstructures using optical lithography.

3. The method of claim 2 wherein optical lithography comprises photolithography.

4. The method of claim 2 wherein the microstructures are formed at an oblique angle to the plane of the substrate.

5. The method of claim 2 wherein optical lithography comprises exposing through a mask.

6. The method of claim 5 wherein the mask comprises a contact mask.

7. The method of claim 1 wherein the nanoparticles comprise indium-tin-oxide.

8. The method of claim 1 wherein etching away at least a portion of the microstructures comprises reactive ion etching.

9. The method of claim 1 wherein the microstructures comprise photoresist.

10. A method of making a replica comprising:
providing a substrate comprising microstructures;
adding nanoparticles to the microstructures;
etching away at least a portion of the microstructures, using the nanoparticles as an etch mask, to form a hierarchical article;
adding a polymer to the hierarchical article; and
separating the polymer from the hierarchical article to produce a replica,
wherein the nanoparticles etch at a substantially slower rate than the substrate.

11. The method of claim 10 further comprising adding a release coating to the hierarchical article before adding the polymer.

12. The method of claim 11 wherein the release coating comprises a fluorosilane.

13. The method of claim 10 further comprising adding a protective coating to the hierarchical article before adding the polymer.

14. The method of claim 13 wherein the protective coating comprises a metal-containing layer.

15. The method of claim 14 further comprising adding a release coating to the metal-containing layer.

16. The method of claim 15 wherein the release coating comprises a fluorinated phosphonic acid.

17. The method of claim 10 wherein the polymer comprises a thermosetting resin.

18. The method of claim 17 further comprising curing the resin.

19. The method of claim 17 wherein the resin comprises a polysiloxane.

20. A replica made according to the method of claim 10.
